(19) United States
(12) Patent Application Publication
(10) Pub. No.: US 2021/0286110 A1
(43) Pub. Date: Sep. 16, 2021

(54) DISPLAY DEVICE

(71) Applicant: Futaba Corporation, Mobara-shi (JP)

(72) Inventors: Satoshi NOGUCHI, Mobara-shi (JP); Youhei FUJIMURA, Mobara-shi (JP); Takahiro NIIYAMA, Mobara-shi (JP)

(21) Appl. No.: 17/191,137

(22) Filed: Mar. 3, 2021

(30) Foreign Application Priority Data
Mar. 11, 2020 (JP) 2020-042361

(51) Int. Cl. G02B 5/02

(52) U.S. Cl. CPC G02B 5/0284; H01L 51/5271

(57) ABSTRACT

In a display device according to the present disclosure, a reflective film surrounding a display region reflects the light from outside from a lower surface side of an element substrate in the same manner as a metal electrode layer of a light emitting display portion covering the display region. Due to reflection occurring in the same manner on an inner side and an outer side of a contour of the display region, the contour of the display region is unlikely to be visually recognized.

### CROSS-REFERENCE TO RELATED APPLICATIONS

This application is based upon and claims the benefit of priority from Japanese Patent Application No. 2020-042361, filed on 11 Mar., 2020, the entire contents of which are incorporated herein by reference.

### TECHNICAL FIELD

The present disclosure relates to a display device.

### BACKGROUND

In the related art, an organic EL display is employed as a small-sized display for in-vehicle use. A display device such as an organic EL display is provided with a display region with a lamination structure having an organic EL light emitting layer interposed between a transparent electrode layer and a metal electrode layer.

### SUMMARY

In the foregoing display device, since the metal electrode layer has a relatively high reflectance, a contour of the display region becomes conspicuous, and this may cause degradation in design. For this reason, a state in which a contour of a display region cannot be seen with the naked eye is desired.

According to the present disclosure, a display device in which a contour of a display region is unlikely to be visually recognized is provided.

According to the present disclosure, there is provided a display device including a substrate having translucency and having a display region, a light emitting display portion having a transparent electrode layer and a metal electrode layer, the transparent electrode layer and the metal electrode layer are parallel to the substrate and overlapping each other with a light emitting layer therebetween, the transparent electrode layer is positioned on a side closer to the substrate than to the metal electrode layer, the light emitting display portion covers entire region of the display region from one surface side of the substrate, and a reflective film surrounding the display region of the substrate along an outer edge of the display region and configured to reflect light from the other surface side of the substrate.

In the foregoing display device, the reflective film surrounding the display region reflects light from the other surface side of the substrate in the same manner as the metal electrode layer of the light emitting display portion covering the display region. In this manner, due to reflection occurring in the same manner on an inner side and an outer side of the display region, a contour of the display region is unlikely to be visually recognized.

The display device according to the aspect may further include a reflected light removal filter covering the other surface of the substrate. In this case, reflected light of the reflective film and the metal electrode layer can be removed.

The display device according to the aspect may further include a light weakening filter covering the other surface of the substrate. In this case, the contour of the display region can be made less likely to he visually recognized.

In the display device according to the aspect, the reflective film may have the same reflectance as the metal electrode layer. In this case, the contour of the display region can be made less likely to be visually recognized.

In the display device according to the aspect, the reflective film may be constituted of the same metal material as the metal electrode layer. In this case, the contour of the display region can be made less likely to be visually recognized.

In the display device according to the aspect, an inner edge of the reflective film may have an overlapping region, the reflective film and the light emitting display portion overlap each other in the overlapping region. At least the overlapping region on a surface of the reflective film on the light emitting display portion side may be an antireflection surface preventing reflection of light of the light emitting display portion. In this case, it is possible to prevent reflection of the light emitted from the light emitting display portion in the surface of the reflective film on the light emitting display portion side.

### BRIEF DESCRIPTION OF THE DRAWINGS

FIG. 1 is a schematic cross-sectional view illustrating a display device according to a first embodiment.

FIG. 2 is an exploded perspective view illustrating some layers in a lamination structure of the display device according to the first embodiment.

FIG. 3 is a view illustrating a display region of the display device according to the first embodiment.

FIG. 4 is a cross-sectional view illustrating a display device according to a second embodiment.

FIG. 5 is a cross-sectional view illustrating a display device according to a third embodiment.

FIG. 6 is a cross-sectional view illustrating a display device according to a fourth embodiment.

FIG. 7 is a cross-sectional view illustrating a display device according to a fifth embodiment.

FIG. 8 is an exploded perspective view illustrating a part of a lamination structure of the display device according to the fifth embodiment.

FIG. 9 is a cross-sectional view illustrating an antireflection having an optical cavity structure.

### DETAILED DESCRIPTION

Hereinafter, embodiments of the present disclosure will be described in detail with reference to the accompanying drawings. In the following description, the same reference signs are used for the same elements or elements having the same function, and duplicate description will be omitted.

### First Embodiment

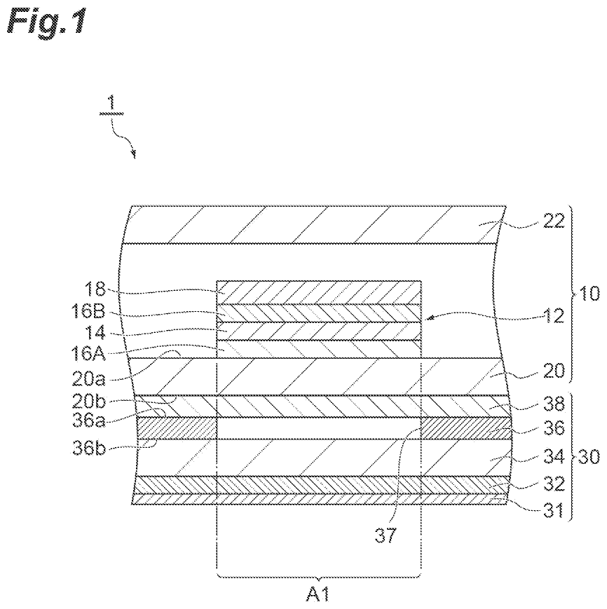

As illustrated in FIG. 1, a display device 1 according to a first embodiment is configured to include a display panel 10 and a mask portion 30. The display device 1 illustrated in FIG. 1 is a bottom emission-type organic EL display device and emits light downward on the paper of FIG. 1.

The display panel 10 has a light emitting display portion 12, an element substrate 20, and a sealing substrate 22.

The element substrate 20 (substrate) is a substrate used when the light emitting display portion 12 is formed. The element substrate 20 has a flat-plate external shape and has an upper surface 20a (one surface) and a lower surface 20b (the other surface). The element substrate 20 is a substrate having translucency and can be constituted of a glass, a resin film, or the like. In the present embodiment, the element substrate 20 is constituted of a transparent glass. A rectangular display region A1 is provided at the center of the element substrate 20.

The sealing substrate 22 is positioned on the upper surface 20a side of the element substrate 20, extends parallel to the element substrate 20, and is separated from the element substrate 20 by a predetermined distance. For example, the sealing substrate 22 is constituted of a glass, a resin, or the like. The sealing substrate 22 may have translucency or may not have translucency. A space between the element substrate 20 and the sealing substrate 22 may be a void or may be filled with a known sealing material.

The light emitting display portion 12 is provided on the upper surface 20a of the element substrate 20 and is positioned between the element substrate 20 and the sealing substrate 22. Specifically, the light emitting display portion 12 is provided such that the entire display region A1 on the upper surface 20a of the element substrate 20 is covered, In the present embodiment, a formation region of the light emitting display portion 12 and the display region A1 of the element substrate 20 are designed such that they coincide with each other. A wiring, a drive circuit, and the like for supplying driving power to the light emitting display portion 12 are provided in a surrounding region A2 of the display region A1 on the upper surface 20a of the element substrate 20, but illustration thereof is omitted. The light emitting display portion 12 has a lamination structure in which a plurality of layers are laminated in a facing direction of the element substrate 20 and the sealing substrate 22 and includes an organic EL light emitting layer 14, a pair of electrode layers 1.6A and 16B, and a sealing layer 18.

The organic EL light emitting layer 14 is a layer including at least an organic compound (light emitting material) emitting light when electrons and positive holes are injected. An organic compound may be a low-molecular-weight compound or may be a high-molecular-weight compound, The organic EL light emitting layer 14 may have an electron injection layer, an electron transportation layer, a positive hole injection layer, a positive hole transportation layer, and the like, in addition to a light emitting layer including the foregoing light emitting material. In addition, the light emitting material of the organic EL light emitting layer 14 may be a fluorescent material, may be a phosphorescent material, or may be a material emitting light of a type different from fluorescence and phosphorescence.

Both the pair of electrode layers 16A and 16B extend parallel to the element substrate 20 and are provided such that they overlap each other with the organic EL light emitting layer 14 therebetween. In the pair of electrode layers 16A and 16B, the electrode layer closer to the element substrate 20 is a transparent electrode layer 16A which functions as an anode, and the transparent electrode layer 16A is directly provided on the upper surface 20a. For example, a constituent material (anode material) of the transparent electrode layer 16A is ITO, IZO, or the like. In the pair of electrode layers 16A and 16B, the electrode layer farther from the element substrate 20 is a metal electrode layer 16B which functions as a cathode. A constituent material (cathode material) of the metal electrode layer 16B is a metal such as Al, Ag, Mg, or Mo or an alloy of these. In the present embodiment, the metal electrode layer 16B is constituted of Al. In the present embodiment, each of the transparent electrode layer 16A and the metal electrode layer 16B is constituted of a plurality of wirings extending in a parallel manner, and each of intersections of the wirings of the transparent electrode layer 16A and the wirings of the metal electrode layer 16B arranged in a mesh shape constitutes a pixel of the light emitting display portion 12.

The sealing layer 18 has a function of preventing exposure of the organic EL light emitting layer 14 and the like to moisture or exposure thereof to air by defining a sealing space between the sealing layer 18 and the sealing substrate 22.

The sealing layer 18 is formed on the metal electrode layer 16B and constitutes an uppermost layer of the light emitting display portion 12. For example, the sealing layer 18 is formed of a material such as SiO, SiN, SiON, SiC, SiOC, AlN, or Al₂O₃.

In the display panel 10 described above, when a voltage is applied between the pair of electrode layers 16A and 16B of the light emitting display portion 12, the organic EL light emitting layer 14 emits light, and the light is emitted downward on the paper of FIG. 1 from the lower surface 20b side of the element substrate 20 via the transparent electrode layer 16A. Light emitted from the organic EL light emitting layer 14 is monochromatic white light, for example.

The mask portion 30 is provided such that the entire lower surface 20b of the element substrate 20 is covered. The mask portion 30 has a lamination structure, in which a light weakening filter 31, a reflected light removal filter 32, a film forming substrate 34, a reflective film 36, and an adhesive layer 38 are arranged in order of those farther from the lower surface 20b of the element substrate 20.

The light weakening filter 31 has a function of weakening light passing therethrough (that is, light incident from outside (from below of FIG. 1) and light emitted from the light emitting display portion 12). As an example, the light weakening filter 31 is a neutral density filter (ND filter).

The reflected light removal filter 32 has a function of selectively removing reflected light when light incident from below of FIG. 1 is reflected by the light emitting display portion 12. In the present embodiment, the reflected light removal filter 32 is a circular polarization filter, which selectively removes only the reflected light from light emitted from the light emitting display portion 12 and reflected light by polarizing light from outside.

The film forming substrate 34 is a flat plate-shaped substrate for forming the reflective film 36. The film forming substrate 34 has translucency and is constituted of a transparent glass in the present embodiment.

The reflective film 36 is formed on an upper surface of the film forming substrate 34 (that is, a surface on the light emitting display portion 12 side). The reflective film 36 is constituted of a material having a predetermined reflectance and can be constituted of a metal, an alloy, a resin, or the like. The reflective film 36 can be constituted of the same material as the constituent material of the metal electrode layer 16B (that is, a metal such as Al, Ag, Mg, or Mo or an alloy of these). In the present embodiment, the reflective film 36 is constituted of Al.

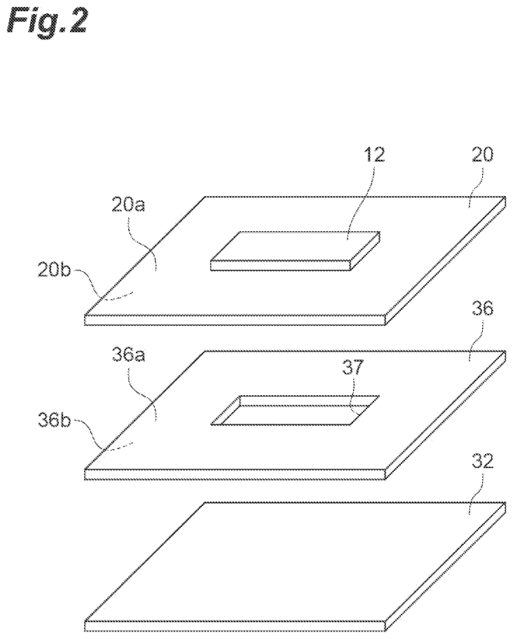

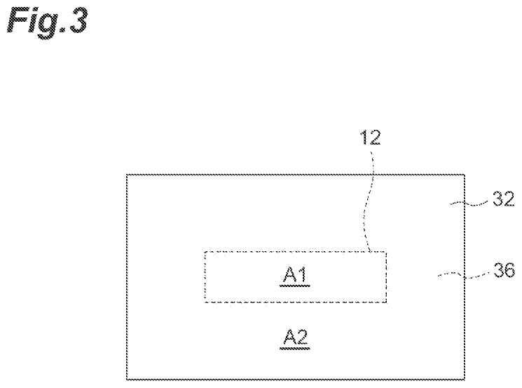

As illustrated in FIGS. 2 and 3, the reflective film 36 is a film having a rectangular ring shape. The reflective film 36 has a rectangular hole 37 at a central part thereof. In the present embodiment, a formation region of the hole 37 of the reflective film 36 and the display region A1 of the element substrate 20 are designed such that they coincide with each other. That is, the reflective film 36 is provided in a region corresponding to the surrounding region A2 of the element substrate 20. In other words, the reflective film 36 surrounds the display region A1 along an outer edge of the display region A1 of the element substrate 20.

The reflective film 36 entirely reflects light incident from below of FIG. 1 on a lower surface 36b thereof. Similar to reflected light in the light emitting display portion 12, reflected light in the reflective film 36 is removed by the reflected light removal filter 32. The thickness of the reflective film 36 need only be a thickness capable of entirely reflecting the light from outside described above and is 100 nm as an example.

The adhesive layer 38 is a layer constituted of an adhesive material for adhering the light weakening filter 31, the reflected light removal filter 32, the film forming substrate 34, and the reflective film 36 described above to the lower surface 20b of the element substrate 20 of the display panel 10. The adhesive layer 38 is a layer having translucency. For example, it may be a molded layer coated with an optical transparent adhesive or may be an optical transparent adhesive sheet.

The display device 1 according to the first embodiment has the element substrate 20 having the display region A1, and the transparent electrode layer 16A and the metal electrode layer 16B overlapping each other with the organic EL light emitting layer 14 therebetween. Moreover, the display device 1 includes the light emitting display portion 12 covering the entire display region A1 of the element substrate 20 from the upper surface 20a side of the element substrate 20, and the reflective film 36 surrounding the display region A1 along the outer edge of the display region A1 of the element substrate 20 and reflecting light from the lower surface 20b side of the element substrate 20.

In the display device 1, the reflective film 36 surrounding the display region A1 reflects light from the lower surface 20b side of the element substrate 20 in the same manner as the metal electrode layer 16B of the light emitting display portion 12 covering the display region Al. In this manner, due to reflection occurring in the same manner on an inner side (that is, the display region A1) and an outer side (that is, the surrounding region A2) of a contour of the display region A1, the contour of the display region A1 is unlikely to be visually recognized.

Particularly, in the display device 1, since the reflective film 36 and the metal electrode layer 16B are constituted of the same metal material (that is, Al;) as each other and have the same reflectance as each other, the display region A1 and the surrounding region A2 reflect light from outside completely in the same manner. For this reason, the contour of the display region A1 is less likely to be visually recognized. The reflectance of the reflective film 36 may be set in accordance with the reflectance of the entire light emitting display portion 12 with respect to light from outside instead of the reflectance of the metal electrode layer 16B alone. In this case, in order to make the reflectance of the reflective film 36 and the reflectance of the entire light emitting display portion 12 close to each other, a dummy organic layer, an edge cover, a separator, or the like may be provided in the light emitting display portion 12. The reflective film 36 may be constituted of a metal material different from that of the metal electrode layer 16B or may have a reflectance different from that of the metal electrode layer 16B. The reflective film 36 may have a thickness such that it can stand. by itself (for example, 5 μm or thicker). In such a case, the film looming substrate 34 can be suitably omitted.

In the display device 1, the reflected light removal filter 32 is provided such that the lower surface 20h of the element substrate 20 is covered. For this reason, when light incident on the display device 1 from outside via the reflected light removal filter 32 is reflected by the light emitting display portion 12 and the reflective film 36, reflected light thereof is removed by the reflected light removal filter 32. Accordingly, reduction in contrast is prevented. In addition, even when the reflectance in the display region A1 and the reflectance in the surrounding region A2 differ from each other, the display region A1 and the surrounding region A2 come in sight in the same manner by preventing the light reflection, and thus the contour of the display region A1 is unlikely to be visually recognized.

In addition, the display device 1 includes the light weakening filter 31 covering the reflected light removal filter 32 from a side opposite to the element substrate 20 side. For this reason, the contour of the display region A1 can be made less likely to be visually recognized. When a light weakening rate of the light weakening filter 31 is high (that is, when the density is high), the contour of the display region A1 is unlikely to be conspicuous, but light emitting extraction efficiency of the light emitting display portion 12 deteriorates. In the display device 1, since the contour of the display region A1 is unlikely to be visually recognized due to the reflective film 36 described above, the density of the light weakening filter 31 can be reduced, or the light weakening filter 31 can be omitted. Therefore, the light emitting extraction efficiency of the light emitting display portion 12 can be enhanced, and sufficient light emission can be obtained while a load of the light emitting display portion 12 is controlled.

### Second Embodiment

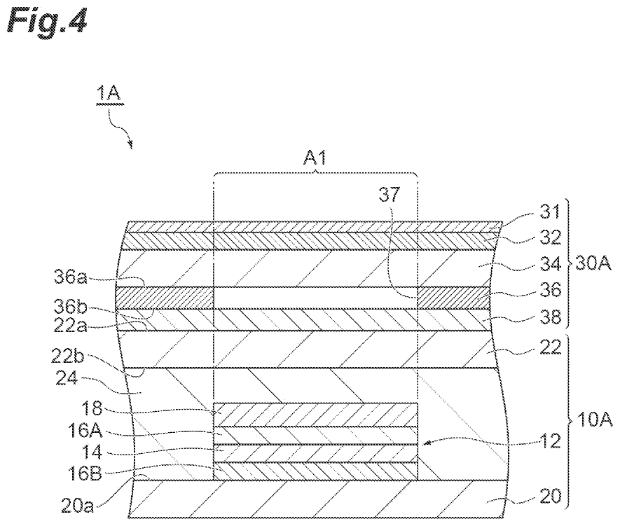

The bottom emission-type display device 1 has been described as the first embodiment, but a top emission-type display device 1A illustrated in FIG. 4 may be adopted. As illustrated in FIG. 4, the display device 1A according to a second embodiment is the same organic EL display device as the display device 1 according to the first embodiment, but this emits light upward on FIG. 4.

The display device 1A is configured to include a display panel 10A and a mask portion 30A.

The display panel 10A has the light emitting display portion 12, the element substrate 20, and the sealing substrate 22.

The element substrate 20 is a substrate used when the light emitting display portion 12 is formed. For example, the element substrate 20 according to the second embodiment is constituted of a glass, a resin, or the like. The element substrate 20 may have translucency or may not have translucency.

The sealing substrate 22 (substrate) is positioned on the upper surface 20a side of the element substrate 20, extends parallel to the element substrate 20, and is separated from the element substrate 20 by a predetermined distance. The sealing substrate 22 has a flat-plate external shape and has an upper surface 22a (the other surface) and a lower surface 22b (one surface). The sealing substrate 22 is a substrate having translucency and is constituted of a transparent glass in the present embodiment. Similar to the display region A1 of the element substrate 20 described in the first embodiment, the display region A1 is provided in the sealing substrate 22. A space between the element substrate 20 and the sealing substrate 22 may be filled with a known sealing material 24, or the sealing layer 18 of the light emitting display portion 12 may come into contact with the sealing substrate 22.

Similar to the light emitting display portion 12 according to the first embodiment, the light emitting display portion 12 according to the second embodiment is provided on the upper surface 20a of the element substrate 20 and is positioned between the element substrate 20 and the sealing substrate 22. Specifically, the light emitting display portion 12 is provided such that the entire display region A1 of the sealing substrate 22 is covered, in the present embodiment, the formation region of the light emitting display portion 12 and the display region A1 of the sealing substrate 22 are designed such that they coincide with each other. Also in the second embodiment, a wiring, a drive circuit, and the like for supplying driving power to the light emitting display portion 12 are provided on the upper surface 20a of the element substrate 20, but illustration thereof is omitted. The light emitting display portion 12 has a lamination structure in which a plurality of layers are laminated in the facing direction of the element substrate 20 and the sealing substrate 22 and includes the organic EL light emitting layer 14, the pair of electrode layers 16A and 16B, and the sealing layer 18.

In the second embodiment, both the pair of electrode layers 16A and 16B extend parallel to the sealing substrate 22 and are provided such that they overlap each other with the organic EL light emitting layer 14 therebetween, In the pair of electrode layers 16A and 16B, the electrode layer closer to the sealing substrate 22 is the transparent electrode layer 16A which functions as an anode. In the pair of electrode layers 16A and 16B, the electrode layer farther from the sealing substrate 22 is the metal electrode layer 16B which functions as a cathode, and the metal electrode layer 16B is directly provided on the upper surface 20a of the element substrate 20. The sealing layer 18 is formed on the transparent electrode layer 16A and constitutes the uppermost layer of the light emitting display portion 12.

In the display panel 10A according to the second embodiment, when a voltage is applied between the pair of electrode layers 16A and 16B of the light emitting display portion 12, the organic EL light emitting layer 14 emits light, and the light is emitted upward on FIG. 4 from the upper surface 22a side of the sealing substrate 22 via the transparent electrode layer 16A.

The mask portion 30A is provided such that the entire upper surface 22a of the sealing substrate 22 is covered. The mask portion 30A has a lamination structure, in which the light weakening filter 31, the reflected light removal filter 32, the film forming substrate 34, the reflective film 36, and the adhesive layer 38 are arranged in order of those farther from the upper surface 22a of the sealing substrate 22. That is, the arrangement order in the mask portion 30A according to the second embodiment is the same as the arrangement order of the mask portion 30 according to the first embodiment.

In the second embodiment, when light incident from above the paper of FIG. 4 is reflected by the light emitting display portion 12 of the display panel 10A, the reflected light removal filter 32 selectively removes the reflected light. The reflective film 36 is formed on a lower surface of the film forming substrate 34 (that is, a surface on the light emitting display portion 12 side), Similar to the reflective film 36 according to the first embodiment, the reflective film 36 according to the second embodiment is a film having a rectangular ring shape and has the rectangular hole 37 at the central part thereof. In the present embodiment, the formation region of the hole 37 of the reflective film 36 and the display region A1 of the sealing substrate 22 are designed such that they coincide with each other. That is, the reflective film 36 is provided in a region corresponding to the surrounding region A2 of the sealing substrate 22. In other words, the reflective film 36 surrounds the display region A1 along the outer edge of the display region A1 of the sealing substrate 22. The reflective film 36 entirely reflects light incident from above the paper of FIG. 4 on an upper surface 36a thereof, Similar to reflected light in the display panel 10A, reflected light in the reflective film 36 is removed by the reflected light removal filter 32.

The display device 1A according to the second embodiment has the sealing substrate 22 having the display region A1, and the transparent electrode layer 16A and the metal electrode layer 16B overlapping each other with the organic EL light emitting layer 14 therebetween. Moreover, the display device 1A includes the light emitting display portion 12 covering the entire display region A1 of the sealing substrate 22 from the lower surface 22b side of the sealing substrate 22, and the reflective film 36 surrounding the display region A1 along the outer edge of the display region A1 of the sealing substrate 22 and reflecting light from the upper surface 22a side of the sealing substrate 22.

Also in the top emission-type display device 1A, similar to the bottom emission-type display device 1, the reflective film 36 surrounding the display region A1 reflects light from the upper surface 22a side of the sealing substrate 22 in the same manner as the metal electrode layer 16B of the light emitting display portion 12 covering the display region A1. In the display device 1A, due to reflection occurring in the same manner on the inner side (that is, the display region A1) and the outer side (that is, the surrounding region A2) of the contour of the display region A1 the contour of the display region A1 is unlikely to be visually recognized.

### Third Embodiment

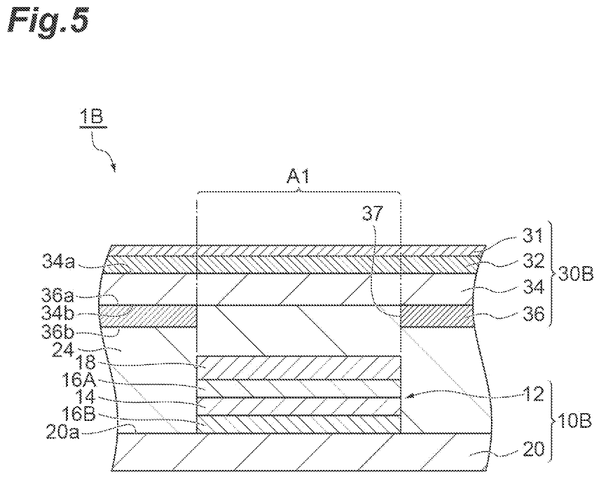

In the configuration of the display device 1A according to the second embodiment, the sealing substrate 22 can be omitted. As illustrated in FIG. 5, a display device 1B according to a third embodiment differs from the display device 1A according to the second embodiment only in that the sealing substrate 22 and the adhesive layer 38 are excluded.

The display device IB is configured to include a display panel 10B and a mask portion 30B. The display panel 10B has the light emitting display portion 12 and the element substrate 20 and does not have the sealing substrate 22.

In the third embodiment, the sealing substrate 22 of the second embodiment is substituted with the film forming substrate 34 of the mask portion 30B.

The film forming substrate 34 (substrate) of the mask portion 30B is positioned on the upper surface 20a side of the element substrate 20, extends parallel to the element substrate 20, and is separated from the element substrate 20 by a predetermined distance. The film forming substrate 34 has a flat-plate external shape and has an upper surface 34a (the other surface) and a lower surface 34b (one surface). The film forming substrate 34 has translucency and is constituted of a transparent glass in the present embodiment. The display region A1 similar to the display region A1 of the element substrate 20 described in the first embodiment is provided in the film forming substrate 34. A space between the element substrate 20 and the film forming substrate 34 may be filled with the known sealing material 24, or the sealing layer 18 of the light emitting display portion 12 may come into contact with the film forming substrate 34.

In the third embodiment, both the pair of electrode layers 16A and 16B extend parallel to the film forming substrate 34 and are provided such that they overlap each other with the organic EL light emitting layer 14 therebetween. In the pair of electrode layers 16A and 16B, the electrode layer closer to the film forming substrate 34 is the transparent electrode layer 16A which functions as an anode. In the pair of electrode layers 16A and 16B, the electrode layer farther from the film forming substrate 34 is the metal electrode layer 16B which functions as a cathode, and the metal electrode layer 16B is directly provided on the upper surface 20a of the element substrate 20. The sealing layer 18 is formed on the transparent electrode layer 16A and constitutes the uppermost layer of the light emitting display portion 12.

In the display panel 10B according to the third embodiment, when a voltage is applied between the pair of electrode layers 16A and 16B of the light emitting display portion 12, the organic EL light emitting layer 14 emits light, and the light is emitted upward on FIG. 5 from the upper surface 34a side of the film forming substrate 34 via the transparent electrode layer 16A.

The display device 1B according to the third embodiment has the film forming substrate 34 having the display region A1, and the transparent electrode layer 16A and the metal electrode layer 16B overlapping each other with the organic EL light emitting layer 14 therebetween. Moreover, the display device 1B includes the light emitting display portion 12 covering the entire display region A1 of the film forming substrate 34 from the lower surface 34b side of the film forming substrate 34, and the reflective film 36 surrounding the display region A1 along the outer edge of the display region A1 of the film forming substrate 34 and reflecting light from the upper surface 34a side of the film forming substrate 34.

Also in the display device 1B which does not have the sealing substrate 22, similar to the display device 1 A having the sealing substrate 22, the reflective film 36 surrounding the display region A1 reflects light from the upper surface 34a side of the film forming substrate 34 in the same manner as the metal electrode layer 16B of the light emitting display portion 12 covering the display region A1. in the display device 1B, due to reflection occurring in the same manner on the inner side (that is, the display region A1) and the outer side (that is, the surrounding region A2) of the contour of the display region A1 the contour of the display region A1 is unlikely to be visually recognized.

In addition, since the display device 1B does not have the sealing substrate 22, a reflection surface of the display region A1 (a reflection surface of the metal electrode layer 16B) and a reflection surface of the surrounding region A2 (that is, a reflection surface of the reflective film 36) are close to each other in a vertical direction. Therefore, compared to the display device 1A, the contour of the display region A1 is less likely to be visually recognized.

In addition, since the display device 1B does not have the sealing substrate 22, the number of components is reduced. Accordingly, the display device is miniaturized (thinned) and manufacturing costs are reduced.

### Fourth Embodiment

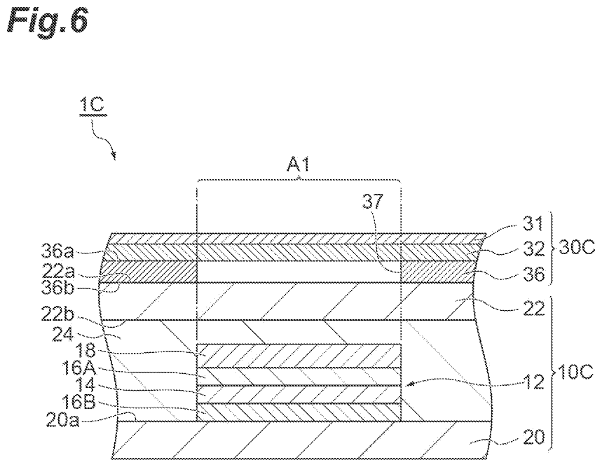

In the configuration of the display device 1A according to the second embodiment, the film forming substrate 34 can be omitted. As illustrated in FIG. 6, a display device 1C according to a fourth embodiment differs from the display device 1A according to the second embodiment only in that the film forming substrate 34 and the adhesive layer 38 are excluded.

The display device IC is configured to include a display panel 10C and a mask portion 30C. The display panel 10C has the same configuration as the display panel 10A according to the second embodiment. The mask portion 30C has the light weakening filter 31, the reflected light removal filter 32, and the reflective film 36 and does not have the film forming substrate 34 and the adhesive layer 38. In the fourth embodiment, the reflective film 36 is directly formed on the upper surface 22a of the sealing substrate 22. That is, the film forming substrate 34 of the second embodiment is substituted with the sealing substrate 22.

The display device 1C according to the fourth embodiment has the sealing substrate 22 having the display region A1, and the transparent electrode layer 16A and the metal electrode layer 16B overlapping each other with the organic EL light emitting layer 14 therebetween. Moreover, the display device 1C includes the light emitting display portion 12 covering the entire display region A1 of the sealing substrate 22 from the lower surface 22b side of the sealing substrate 22, and the reflective film 36 surrounding the display region A1 along the outer edge of the display region A1 of the sealing substrate 22 and reflecting light from the upper surface 22a side of the sealing substrate 22.

Also in the display device 1C, which does not have the film forming substrate 34, similar to the display device 1A having the film forming substrate 34, the reflective film 36 surrounding the display region A1 reflects light from the upper surface 22a side of the sealing substrate 22 in the same manner as the metal electrode layer 16B of the light emitting display portion 12 covering the display region A1. In the display device 1C, due to reflection occurring in the same manner on the inner side (that is, the display region A1) and the outer side (that is, the surrounding region A2) of the contour of the display region A1 the contour of the display region A1 is unlikely to be visually recognized.

Since the display device does not have the film forming substrate 34, the reflection surface of the display region A1 (the reflection surface of the metal electrode layer 16B) and the reflection surface of the surrounding region A2 (that is, the reflection surface of the reflective film 36) are close to each other in the vertical direction. Therefore, compared to the display device 1A, the contour of the display region A1 is less likely to be visually recognized.

In addition, since the display device 1C does not have the film forming substrate 34, the number of components is reduced. Accordingly, the display device is miniaturized (thinned) and manufacturing costs are reduced.

### Fifth Embodiment

All of the first embodiment to the fourth embodiment described above have a form in which the formation region of the light emitting display portion 12 coincides with the display region A1, but a form in which the formation region of the light emitting display portion 12 is larger than the display region A1 may be adopted.

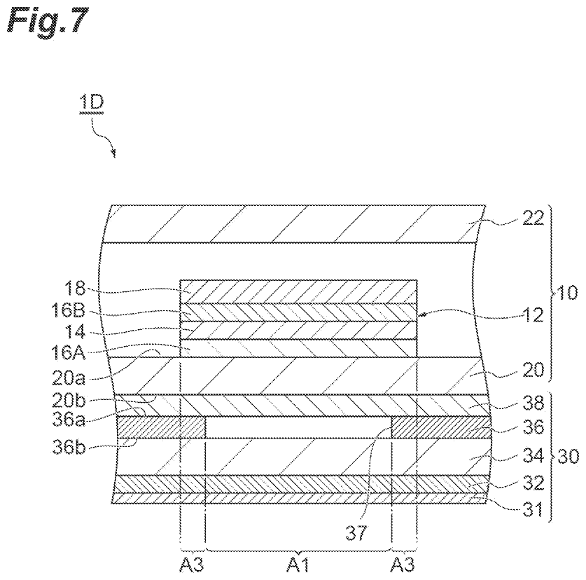

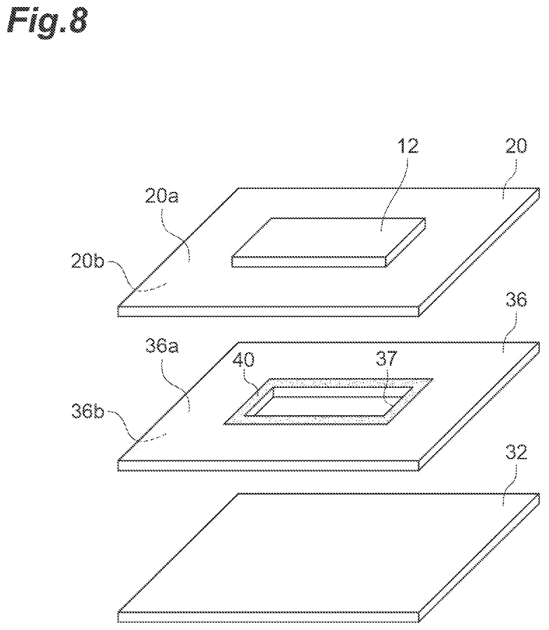

As illustrated in FIGS. 7 and 8, a display device 1D according to a fifth embodiment has an overlapping region A3 in which the reflective film 36 and the light emitting display portion 12 overlap each other. More specifically, the overlapping region A3 is a region having a. rectangular ring shape in which an inner edge of the reflective film 36 and an outer edge of the light emitting display portion overlap each other. Further, as illustrated in FIG. 8, the overlapping region A3 on the upper surface 36a of the reflective film 36 serves as an antireflection surface 40. The antireflection surface 40 is provided on a surface (that is, the upper surface 36a) of the reflective film 36 on the light emitting display portion 12 side and prevents reflection of light emitted from the light emitting display portion 12 by the reflective film 36.

As an example, the antireflection surface 40 can be formed by coating and coloring the overlapping region A3 on the upper surface 36a of the reflective film 36 with a pigmented ink using a permanent marker or the like. The color of the pigmented ink may be black or color other than black. As another example, the antireflection surface 40 may be a colored thin film or the like formed on the upper surface 36a of the reflective film 36.

When the formation region of the light emitting display portion 12 is slightly smaller than the display region A1, the contour of the display region A1 becomes conspicuous and degradation in design may be caused due to a gap between the formation region of the light emitting display portion 12 and the display region A1. in order to avoid such degradation in design, the formation region of the light emitting display portion 12 and the display region A1 are designed such that they coincide with each other or are designed such that the formation region of the light emitting display portion 12 is larger than the display region A1. In a display device in which the formation region of the light emitting display portion 12 and the display region A1 coincide with each other, high positioning accuracy is required at the time of manufacturing the device. Therefore, it is easier to manufacture a display device in which the formation region of the light emitting display portion 12 is larger than the display region A1. Even in the display device 1D in which the formation region of the light emitting display portion 12 is larger than the display region A1, when the antireflection surface 40 is not present, for instance, light emitted from the light emitting display portion 12 is reflected by the upper surface 36a of the reflective film 36 in the overlapping region A3. in this case, light spots are generated on the light emitting display portion 12 due to reflected light in the reflective film 36, and thus a similar reflection image (minor image) is displayed in the light emitting display portion 12 in addition to images (characters, figures, or the like) actually displayed by light emission.

In the display device 1D, due to the antireflection surface 40, occurrence of a situation in which light emitted from the light emitting display portion 12 is reflected by the upper surface 36a of the reflective film 36 is prevented, and thus a reflection image is unlikely to be displayed.

in the reflective film 36, only the overlapping region A3 on the upper surface 36a may serve as the antireflection surface 40, or the entire upper surface 36a may serve as the antireflection surface 40.

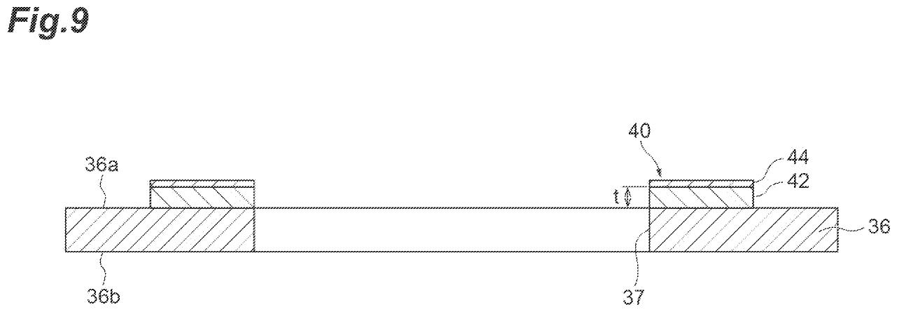

In addition, the antireflection surface 40 may be realized by an optical cavity structure. FIG. 9 illustrates a form in which the antireflection surface 40 of the reflective film 36 has an optical cavity structure. The optical cavity structure illustrated. in FIG. 9 has a light guide layer 42 and a semi-reflective film 44 provided on the upper surface 36a of the reflective film 36, and light taken in from the semi-reflective film 44 side is confined between the reflective film 36 and the semi-reflective film 44.

The semi-reflective film 44 can be constituted of metal such as Al, Ag, Mg, Mo, or Cr or an alloy of these. The semi-reflective film 44 is designed to have a thickness with which semi-reflection (that is, a part of light is reflected and a part is transmitted through) may occur. For example, when the semi-reflective film 44 is constituted of A1, the thickness thereof is within a range of approximately 30 to 70 Å. The light guide layer 42 is an organic material layer constituted of an organic material, for example. The light guide layer 42 can confine the entire light emission spectrum of the light emitting display portion 12 in the optical cavity structure by adjusting a thickness t thereof. Here, in the optical cavity structure, only light having a wavelength of an integral multiple of 2×t×n (t: a thickness of the light guide layer 42, and a refractive index of the light guide layer 42) is resonated and output to outside. Therefore, when light emitted from the organic EL light emitting layer 14 of the light emitting display portion 12 is monochromatic white light, the light guide layer 42 is designed such that the thickness t thereof becomes 70 mu or thicker, and thus the entire light emission spectrum of the light emitting display portion 12 can be confined in the optical cavity structure.

The present disclosure is not limited to the embodiments described above and can be variously deformed. For example, a flat surface shape of the display region is not limited to a rectangular shape and may be a circular shape, an oval shape, or a polygonal shape.

What is claimed is:

1. A display device comprising:
a substrate having translucency and having a display region;
a light emitting display portion having a transparent electrode layer and a metal electrode layer, the transparent electrode layer and the metal electrode layer are parallel to the substrate and overlapping each other with a light emitting layer therebetween, the transparent electrode layer is positioned on a side closer to the substrate than to the metal electrode layer, the light emitting display portion covers entire region of the display region from one surface side of the substrate; and
a reflective film surrounding the display region of the substrate along an outer edge of the display region and configured to reflect light from the other surface side of the substrate.

2. The display device according to claim 1 further comprising:
a reflected light removal filter covering the other surface of the substrate.

3. The display device according to claim 2 further comprising:
a light weakening filter covering the other surface of the substrate.

4. The display device according to claim 1,
wherein the reflective film has the same reflectance as the metal electrode layer.

5. The display device according to claim 4,
wherein the reflective film is constituted of the same metal material as the metal electrode layer.

6. The display device according to claim 1,
wherein an inner edge of the reflective film has an overlapping region, the reflective film and the light emitting display portion overlap each other in the overlapping region,
wherein at least the overlapping region on a surface of the reflective film on the light emitting display portion side is an antireflection surface preventing reflection of light of the light emitting display portion.
